(19) United States
(12) Patent Application Publication
(10) Pub. No.: US 2006/0042676 A1
(43) Pub. Date: Mar. 2, 2006

(54) Thermoelectric device and method of manufacturing the same

(75) Inventors: Takahiro Sogou, Yokohama-shi (JP); Kazuki Tateyama, Yokohama-shi (JP); Hiroyoshi Hanada, Yokohama-shi (JP); Naruhito Kondo, Kawasaki-shi (JP); Yasuhito Saito, Yokohama-shi (JP); Masayuki Arakawa, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/206,916

(22) Filed: Aug. 19, 2005

(30) Foreign Application Priority Data
Aug. 31, 2004 (JP) 2004-252849

(51) Int. Cl. H01L 35/30; H01L 35/28

(52) U.S. Cl. 136/212; 136/205

(57) ABSTRACT

In order that a thermoelectric device is caused to stably operate even under high temperature environment, the thermoelectric device includes: first and second substrates, each being provided with a plurality of electrodes; a plurality of thermoelectric elements arranged between the first and second substrates in such a manner that one ends of the thermoelectric elements are associated with the respective electrodes on the first substrate, and the other ends thereof are associated with the respective electrodes on the second substrate; a defining member defining positions of the respective thermoelectric elements; and a lid disposed outside of the second substrate, and connected to the first substrate in such a manner that pressure is applied between the second substrate and the first substrate.

### CROSS-REFERENCE TO RELATED APPLICATIONS

This application is based upon and claims the benefit of priority from Japanese Patent Application No. 2004-252849 filed Aug. 31, 2004; the entire contents of which are incorporated herein by reference.

### BACKGROUND OF THE INVENTION

1. Field of the Invention

The present invention relates to a thermoelectric device which is capable of converting heat into electricity, or converting electricity into heat, and to a method of manufacturing a thermoelectric device.

2. Description of the Related Art

A thermoelectric device is composed by thermoelectric elements using the thermoelectric effect, such as the Thomson effect, the Peltier effect, and the Seebeck effect. Thermoelectric devices as temperature control units have already been in mass production. Research and development on thermoelectric devices as power generation units for converting heat into electricity are underway.

The thermoelectric device as the power generation unit has a structure in which a plurality of p-type thermoelectric elements and n-type thermoelectric elements are sandwiched between a first substrate having a plurality of electrodes and a second substrate having a plurality of electrodes. The thermoelectric elements generate an electromotive force due to a temperature difference at both ends. One ends of the thermoelectric elements are respectively connected to the electrodes on the first substrate, and the other ends are respectively connected to the electrodes on the second substrate, by solder. Then all the thermoelectric elements are connected electrically in series. In addition, these thermoelectric elements are arranged thermally in parallel.

In order to approximate the generation efficiency of the thermoelectric device at the time of converting heat into electricity to the generation efficiency of the thermoelectric element itself, it is necessary that heat supply to one end of the thermoelectric element and heat dissipation from the other end of the thermoelectric element are made smoothly. Accordingly, ceramic substrates, which are excellent in thermal conductivity, are used for the first and second substrates included in the thermoelectric device. Electrically conductive material, such as copper which is low in electrical resistance, is used for the electrodes to which the thermoelectric elements are connected.

However, since the melting point of the solder is approximately 150 to 300° C., when the thermoelectric device in which solder is used is caused to operate under high temperature environment, at 900° C., for example, there is a problem that reliability in operation is imparted due to melting of solder.

### SUMMARY OF THE INVENTION

An object of the present invention is to provide a thermoelectric device which operates even under high temperature environment, and has higher reliability, and a method of manufacturing the thermoelectric device.

A thermoelectric device according to the present invention includes: first and second substrates, each being provided with a plurality of electrodes; a plurality of thermoelectric elements arranged between the first and second substrates in such a manner that one ends of the thermoelectric elements are associated with the respective electrodes on the first substrate, and the other ends thereof are associated with the respective electrodes on the second substrate; a defining member defining positions of the respective thermoelectric elements; and a lid disposed outside of the second substrate, and connected to the first substrate in such a manner that pressure is applied between the second substrate and the first substrate.

In the present invention, since the thermoelectric device is provided with a defining member, which defines positions of the respective thermoelectric elements, the solder, which has heretofore connected thermoelectric elements to electrodes, becomes unnecessary. In addition, since it is possible to hold the thermoelectric elements by means of the pressure applied in the height direction of the thermoelectric element, even if the thermoelectric device is heated and thermally deformed, sliding occurs at the interface between each thermoelectric element and the corresponding electrode, thereby making it possible to prevent damage of the elements, and the like.

In the above thermoelectric device, it is desirable that a tip of a portion extending from an edge segment of the lid be connected to the first substrate in such a manner that the defining member is held by the portion.

Thus, it is made possible to hold the defining member without providing any other members. In addition, by using the portion extending from the edge segment of the lid, it is facilitated to align the defining member with the first substrate.

In the above thermoelectric device, it is desirable that a width of the portion extending from the edge segment of the lid be smaller than a length of a side of the lid.

Thus, the portions each extending from an edge segment of the lid are allowed to exhibit high thermal resistance when heat is supplied to the lid, so that it is made possible to decrease the quantity of heat flowing to the first substrate side through these portions.

In the above thermoelectric device, it is desirable that the defining member be an insulative material having through holes at the positions corresponding to the respective thermoelectric elements, the through holes defining the positions of the corresponding thermoelectric elements.

Thus, the positions of the thermoelectric elements can be defined in such a manner that the thermoelectric elements are prevented from electrically affecting one another.

In addition, a method of manufacturing a thermoelectric device according to the present invention includes: disposing a defining member on a first substrate provided with a plurality of electrodes, the defining member defining positions of one ends of a plurality of thermoelectric elements in such a manner that the one ends of the thermoelectric elements are associated with the respective electrodes; arranging the plurality of thermoelectric elements at the positions defined by the defining member on the first substrate; placing a second substrate provided with a plurality of electrodes oppositely to the first substrate in such a manner that the electrodes are associated with the other ends of the thermoelectric elements; and connecting a lid to the first substrate in such a manner that pressure is applied between the second substrate and the first substrate, the lid being disposed outside of the second substrate.

In the above method of manufacturing a thermoelectric device, it is desirable that, in the connecting step, a tip of a portion extending from an edge segment of the lid be connected to the first substrate in such a manner that the defining member is held by the portion.

In addition, in the above method of manufacturing a thermoelectric device, it is desirable that, the lid which is formed in such a shape that a width of the portion extending from the edge segment of the lid is smaller than a length of a side of the lid, be used.

In the above method of manufacturing a thermoelectric device, it is desirable that an insulative material having through holes at the positions corresponding to the respective thermoelectric elements be used for the defining member, the through holes defining the positions of the corresponding thermoelectric elements.

### BRIEF DESCRIPTION OF DRAWINGS

FIG. 1 is a cross-sectional view showing a configuration of a thermoelectric device of an embodiment.

FIG. 2 is a perspective view showing the configuration of the thermoelectric device of the embodiment.

FIG. 3 is a perspective view of a defining member of the thermoelectric device of the embodiment.

FIG. 4 is a cross-sectional view showing part of a first manufacturing step for the thermoelectric device of the embodiment.

FIG. 5 is a cross-sectional view showing part of the first manufacturing step for the thermoelectric device of the embodiment.

FIG. 6 is a cross-sectional view showing part of a second manufacturing step for the thermoelectric device of the embodiment.

FIG. 7 is a cross-sectional view showing part of a third manufacturing step for the thermoelectric device of the embodiment.

### DESCRIPTION OF THE EMBODIMENT

A description will be given below of an embodiment of the present invention with the use of drawings.

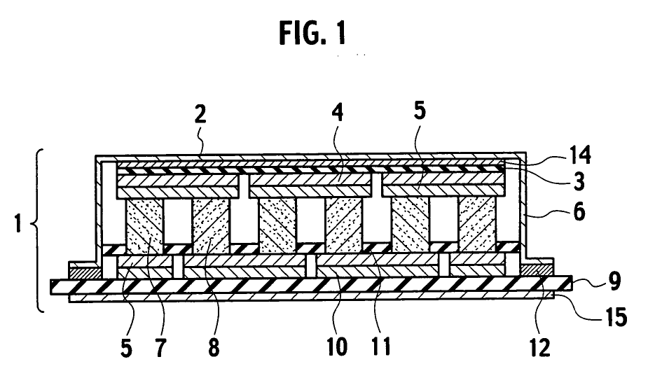

FIG. 1 is a cross-sectional view showing a configuration of a thermoelectric device of the embodiment. The thermoelectric device 1 in FIG. 1 includes: a first substrate 9 which is insulative and provided with a plurality of electrodes 10 and lid connecting electrodes 12; a second substrate 3 which is insulative and provided with a plurality of electrodes 4; a plurality of p-type thermoelectric elements 7 and a plurality of n-type thermoelectric elements 8; a defining member 11 which defines positions of the respective thermoelectric elements; and a lid 2. The electrodes 10 and the electrodes 4 are arranged on the first substrate 9 and the second substrate 3, respectively, in such a manner that all the thermoelectric elements are connected electrically in series. Here, by way of example, SiN-based ceramics is used for the first substrate 9 and the second substrate 3, and copper with low electric resistance is used for the electrodes 4 and the electrodes 10.

The plurality of p-type thermoelectric elements 7 and the plurality of n-type thermoelectric elements 8 are regularly arranged between the first substrate 9 and the second substrate 3 in such a manner that one end of an element is associated with an electrode 10 on the first substrate 9 and the other end of the element is associated with an electrode 4 on the second substrate 3. Here, by way of example, as the p-type thermoelectric elements 7 and the n-type thermoelectric elements 8, those which have the Half-Heusler structure, which have high heat resistance, are used.

Between each of the thermoelectric elements 7 and 8 and the corresponding electrode 4 or 10, an elastic metal piece 5 is placed, which is formed by weaving copper metal fibers. The elastic metal pieces 5 are fixed to the respective electrodes 4 and 10 by resistance welding. Since the elastic metal piece 5 has a property of resiliently deforming, when the thermoelectric elements 7 and 8 are thermally deformed under high temperature environment, expansion and contraction in the height direction are absorbed by virtue of this construction. In addition, the elastic metal pieces 5 absorb the variations in the height of the thermoelectric elements 7 and 8 caused during manufacturing, and the variations caused during assembling due to the warpage of the first and second substrates 9 and 3.

The defining member 11 is disposed on the first substrate 9 so as to define the positions of the thermoelectric elements 7 and 8. The lid 2 is disposed outside of the second substrate 3; tips of portions 6 each extending from an edge segment of the lid 2 are connected to the first substrate 9 by the lid connecting electrodes 12 in such a manner that pressure is applied between the second substrate 3 and the first substrate 9. Details of the configurations of the defining member 11 and the lid 2 will be described later.

The thermoelectric device 1 brings the lid 2 into contact with the heat source of 900° C., for example, and supplies the heat to the second substrate 3. And the thermoelectric device 1 sets the first substrate 9 to a temperature below 900° C. by radiating heat from the first substrate 9. Thus the thermoelectric device 1 generates electricity by causing a temperature difference, which temperature difference is generated across the thermoelectric elements 7 and 8. Here, it is also possible that the thermoelectric device 1 operates by bringing the second substrate 3 into contact with the heat source and radiating heat from lid 2. Here, a metal film 14 with high thermal conductivity is formed between the lid 2 and the second substrate 3, and a metal film 15 is similarly formed on the outside of the first substrate 9, thereby allowing heat to flow smoothly to and from the outside, and increasing thermal efficiency.

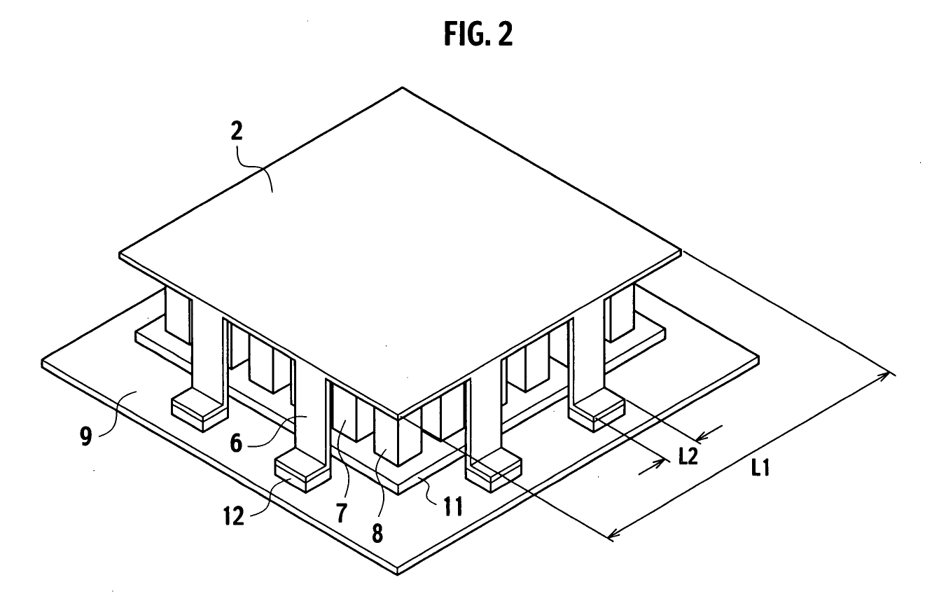

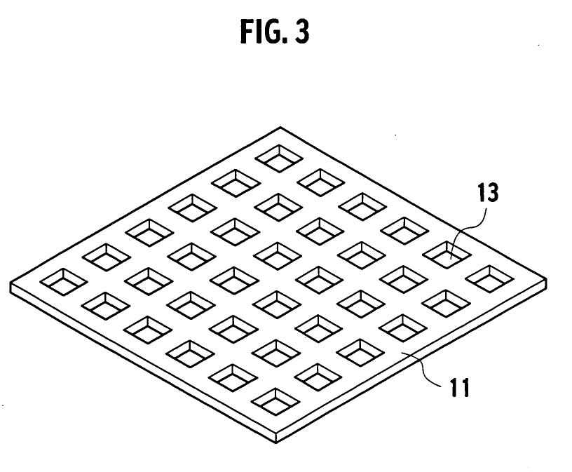

Next, a description will be given of the defining member 11 with the use of FIGS. 2 and 3.

FIG. 2 is a perspective view showing the configuration of the thermoelectric device. In FIG. 2, the defining member 11 is disposed on the first substrate 9 in parallel with the lid 2 and the first substrate 9.

FIG. 3 is a perspective view showing the configuration of the defining member 11. As shown in FIG. 3, the defining member 11 is an insulating material which has through holes 13 for defining the positions of the thermoelectric elements at the positions corresponding to the respective thermoelectric elements. As shown in FIG. 2, one end of each of the thermoelectric elements 7 and 8 is inserted into a through hole 13 in the defining member 11, and is brought into electrical contact with the electrode 4 and 10. Here, a highly insulative and heat-resistant ceramic material is used for the defining member 11 in consideration of the operating temperature and the fact that the defining member 11 comes into contact with the thermoelectric elements. By using ceramics for the defining member 11 in such a manner, even under high temperature environment, the thermoelectric elements are prevented from electrically affecting one another.

Next, a description will be given of the lid 2 with the use of FIG. 2.

As shown in FIG. 2, the tips of portions 6 each extending from an edge segment of the lid 2 are connected to the first substrate 9 in such a manner that the defining member 11 is held by the portions 6. By holding the defining member 11 by the use of the portions 6 each extending from an edge segment of the lid 2, it is made unnecessary to provide another member for holding the defining member 11. By holding the defining member 11 by the use of the first substrate 9 and the portions 6 each extending from an edge segment of the lid 2, the position of the defining member 11 is determined, and the alignment between the defining member 11 and the first substrate 9 is facilitated.

The tips of the portions 6 each extending from an edge segment of the lid 2 are connected with the lid connecting electrodes 12 on the first substrate 9. For example, if the operating temperature on the first substrate 9 side is set to a temperature below 900° C., metal foil, which is weldable, is used for the lid connecting electrodes 12, and the portion 6 each extending from an edge segment of the lid 2 and the lid connecting electrode 12 are joined by laser welding. In addition, for heat resistance and reduction in difference between thermal deformations of the lid 2 and the first substrate 9, kovar, which can be laser-welded to the metal foil that is the lid connecting electrode 12, is used for the lid 2.

Moreover, in FIG. 2, a width L2 of the portion 6 extending from an edge segment of the lid 2 is smaller than a length L1 of a side of the lid 2. Thus, it is made possible to increase the thermal resistance of the portion 6 extending from an edge segment of the lid 2, and to achieve reduction in the quantity of heat flowing into the first substrate 9 side through the portions 6 each extending from an edge segment of the lid 2. Furthermore, in this embodiment, two portions 6 each extending from an edge segment of the lid 2 are provided for each side of the lid 2. Thus, stability of the lid 2 is secured.

The thermoelectric device of this embodiment can be realized by using a manufacturing process described below, for example.

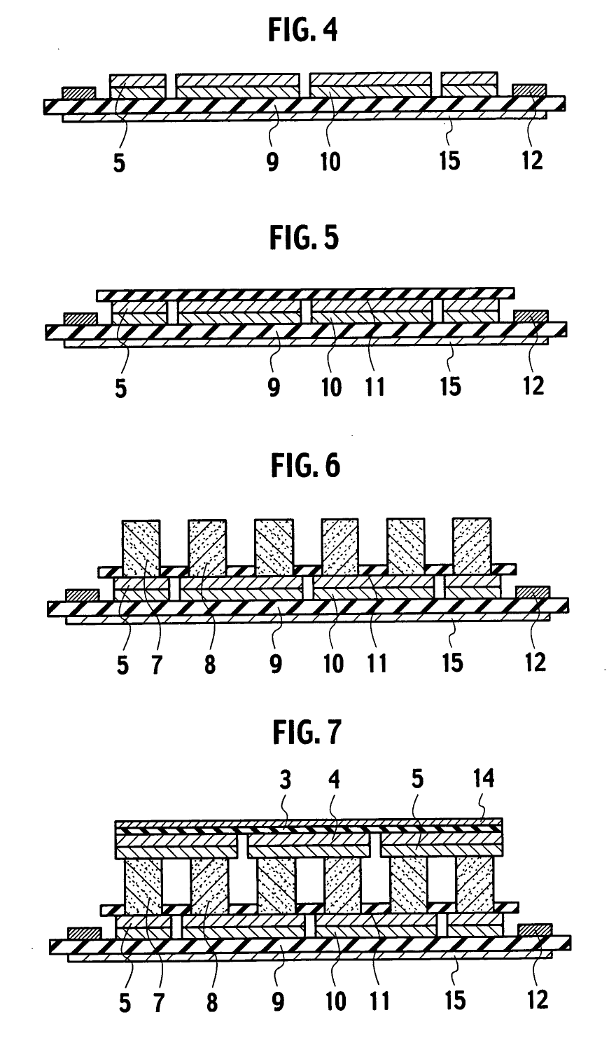

First of all, in a first manufacturing step, as shown in FIG. 4, the plurality of electrodes 10 and the lid connecting electrodes 12 are arranged on the first substrate 9, and the elastic metal pieces 5, which are formed by weaving metal fibers, are fixed thereon by resistance welding in such a manner as to be associated with the respective electrodes 10. The metal film 15, which has a high thermal conductivity, is formed on the outside of the first substrate 9. Subsequently, as shown in FIG. 5, the defining member 11, which defines positions of one ends of the respective thermoelectric elements, is disposed on the first substrate 9.

In a second manufacturing step, as shown in FIG. 6, the plurality of thermoelectric elements 7 and 8 are arranged at the positions defined by the defining member 11. Thus, the positions of the respective thermoelectric elements 7 and 8 are defined without using any joining members.

In a third manufacturing step, as shown in FIG. 7, the second substrate 3 on which the plurality of electrodes 4 have been arranged is placed opposite the first substrate 9 in such a manner that each electrode 4 is associated with one end of each of the thermoelectric elements. Incidentally, for the second substrate 3, used is one on which the elastic metal pieces 5 are previously fixed at the positions corresponding to the respective electrodes 4, and the metal film 14 is formed on a surface facing the surface of the second substrate 3 on which the plurality of electrodes 4 are arranged.

Lastly, as shown in FIG. 1, the lid 2 is disposed outside of the second substrate 3, and the lid 2 is connected to the first substrate 9 in such a manner that pressure is applied between the second substrate 3 and the first substrate 9. At this time, the tips of portions 6 each extending from an edge segment of the lid 2 are connected to the first substrate 9 in such a manner that the defining member 11 is held by the portions 6. At the time of connection, each portion 6 extending from an edge segment of the lid 2 and each lid connecting electrode 12 on the first substrate 9 are welded together.

By means of the above steps, the thermoelectric elements 7 and 8 are held by the first substrate 9 and the second substrate 3, and thus the thermoelectric device 1 can be obtained. Here, for the width L2 of the portion 6 extending from an edge segment of the lid 2, employed is one obtained by forming the portion 6 with the width thereof smaller than the length L1 of a side of the lid 2 as shown in FIG. 2. By holding the defining member 11 by the use of the first substrate 9 and the portions 6 each extending from an edge segment of the lid 2 in this way, the position of the defining member 11 is determined, and the alignment between the defining member 11 and the first substrate 9 is facilitated. In addition, the alignment between the second substrate 3 and the thermoelectric elements is also facilitated, and thus the facility of assembling the thermoelectric device 1 is increased.

Thus, according to this embodiment, the positions of the thermoelectric elements are defined by the defining member, so that the solder, which has heretofore joined thermoelectric elements to electrodes, becomes unnecessary. For this reason, even under high temperature environment, at 900° C., for example, it is possible to cause the thermoelectric device to operate with high reliability.

In this embodiment, an insulative material in which through holes are made is used for the defining member. Thus, the positions of the thermoelectric elements can be defined in such a manner that the thermoelectric elements are prevented from electrically affecting one another.

In this embodiment, the thermoelectric elements are held by means of the pressure applied in the height direction of the thermoelectric element by the lid disposed outside of the second substrate. Thus, even if the thermoelectric device is heated and thermally deformed, sliding occurs at the interface between each thermoelectric element and the corresponding electrode, thereby making it possible to prevent damage of the elements, and the like. Moreover, the thermoelectric device is capable of stably operating in a high temperature region, at 900° C., for example. Therefore, it is possible to increase reliability.

In this embodiment, the tips of the portions each extending from an edge segment of the lid are connected to the first substrate. Thus, it is possible to hold the defining member without providing any other members, and to prevent the increase in manufacturing cost. Moreover, by using the portions each extending from an edge segment of the lid, it is facilitated to align the defining member with the first substrate.

In this embodiment, the width of the portion extending from an edge segment of the lid is made smaller than the length of a side of the lid. Thus, the portions each extending from an edge segment of the lid are allowed to exhibit high thermal resistance when heat is supplied to the lid, so that it is made possible to decrease the quantity of heat flowing to the first substrate side through these portions. As a result, it is made possible to prevent the decrease of power generation efficiency by controlling the rise of the temperature of the second substrate, and enlarging a temperature difference at both ends of the thermoelectric elements.

It should be noted that, although the elastic metal piece made of copper, which is formed by weaving metal fibers, is used for the member interposed between each thermoelectric element and the corresponding electrode in the above embodiment, the member is not limited to this. The member may be a metal plate spring or helical spring, for example, as long as the member has a property of resiliently deforming, and has a function of absorbing the variations in the height direction of the thermoelectric elements. Moreover, with regard to material, although copper is used in view of resistance and thermal conductivity, the material is not limited to this. In the case of a higher operating temperature, the elastic metal piece may be made of a highly heat-resistant stainless steel.

It should also be noted that, in the above embodiment, for heat resistance and reduction of difference between thermal deformations of the lid and the first substrate, kovar is chosen for the lid, which can be laser-welded to the metal foil that is the lid connecting electrode. However, the material is not limited to kovar, unless the material decreases power generation efficiency of the thermoelectric device.

It should also be noted that, although two portions each extending from an edge segment of the lid are provided for each side of the lid in the above embodiment, the number of the portions is not limited to this. In the case of one portion for each side, for example, the portions each extending from an edge segment of the lid are allowed to exhibit higher thermal resistance when heat is supplied to the lid, so that it is made possible to further limit the quantity of heat flowing to the first substrate side through these portions. On the other hand, in the case of three or four portions for each side, it is possible to secure further stability of the position of the defining member held by the lid.

It should also be noted that, although the description has been given of a case in which power generation is performed utilizing temperature difference, it is also possible to use the thermoelectric device as the Peltier module, which causes heat transfer by energizing the device.

What is claimed is:

1. A thermoelectric device comprising:
first and second substrates, each being provided with a plurality of electrodes;
a plurality of thermoelectric elements arranged between the first and second substrates in such a manner that one ends of the thermoelectric elements are associated with the respective electrodes on the first substrate, and the other ends thereof are associated with the respective electrodes on the second substrate;
a defining member defining positions of the respective thermoelectric elements; and
a lid disposed outside of the second substrate, and connected to the first substrate in such a manner that pressure is applied between the second substrate and the first substrate.

2. The thermoelectric device according to claim 1, wherein
a tip of a portion extending from an edge segment of the lid is connected to the first substrate in such a manner that the defining member is held by the portion.

3. The thermoelectric device according to claim 2, wherein
a width of the portion extending from the edge segment of the lid is smaller than a length of a side of the lid.

4. The thermoelectric device according to claim 1, wherein
the defining member is an insulative material having through holes at the positions corresponding to the respective thermoelectric elements, the through holes defining the positions of the corresponding thermoelectric elements.

5. A method of manufacturing a thermoelectric device, comprising:
disposing a defining member on a first substrate provided with a plurality of electrodes, the defining member defining positions of one ends of a plurality of thermoelectric elements in such a manner that the one ends of the thermoelectric elements are associated with the respective electrodes;
arranging the plurality of thermoelectric elements at the positions defined by the defining member on the first substrate;
placing a second substrate provided with a plurality of electrodes oppositely to the first substrate in such a manner that the electrodes are associated with the other ends of the thermoelectric elements; and
connecting a lid to the first substrate in such a manner that pressure is applied between the second substrate and the first substrate, the lid being disposed outside of the second substrate.

6. The method of manufacturing a thermoelectric device according to claim 5, wherein,
in the connecting step, a tip of a portion extending from an edge segment of the lid is connected to the first substrate in such a manner that the defining member is held by the portion.

7. The method of manufacturing a thermoelectric device according to claim 6, wherein
used is the lid which is formed in such a shape that a width of the portion extending from the edge segment of the lid is smaller than a length of a side of the lid.

8. The method of manufacturing a thermoelectric device according to claim 5, wherein
an insulative material having through holes at the positions corresponding to the respective thermoelectric elements is used for the defining member, the through holes defining the positions of the corresponding thermoelectric elements.
